(19) United States
(12) Patent Application Publication
(10) Pub. No.: US 2016/0201193 A1
(43) Pub. Date: Jul. 14, 2016

(54) Substrate Processing Apparatus, Gas Dispersion Unit, Method of Manufacturing Semiconductor Device and Non-Transitory Computer-Readable Recording Medium

(71) Applicant: Hitachi Kokusai Electric Inc., Tokyo (JP)

(72) Inventor: Shuhei SAIDO, Toyama (JP)

(21) Appl. No.: 14/669,982

(22) Filed: Mar. 26, 2015

(30) Foreign Application Priority Data
Jan. 9, 2015 (JP) 2015-003170

(51) Int. Cl. C23C 16/455; C23C 16/458; C23C 16/50

(52) U.S. Cl. CPC C23C 16/455; C23C 16/50; C23C 16/458

(57) ABSTRACT

Characteristics of a film formed on a substrate and a manufacturing throughput can be improved. A substrate processing apparatus includes a process chamber configured to process a substrate; a substrate placement unit; and a gas dispersion unit, the gas dispersion unit including: a first supply region facing the substrate and including a first gas dispersion hole configured to supply a first gas and a second gas dispersion hole configured to supply a second gas; and a second supply region facing a portion of a surface of the substrate placement unit outer than a portion of the surface of the substrate placement unit occupied by the substrate and including a third gas dispersion hole having a diameter greater than that of the second gas dispersion hole and configured to supply the second gas.

### CROSS REFERENCE TO RELATED APPLICATIONS

This application claims foreign priority under 35 U.S.C. §119(a)-(d) to Application No. JP 2015-003170 filed on Jan. 9, 2015, the entire contents of which are hereby incorporated by reference.

### FIELD OF THE INVENTION

The present invention relates to a substrate processing apparatus, a gas dispersion unit, a method of manufacturing a semiconductor device and a non-transitory computer-readable recording medium.

### BACKGROUND

As semiconductor devices (e.g., integrated circuits (ICs)), and particularly dynamic random access memories (DRAMs), have been developed to be highly integrated and efficient, there is a need to develop a technology of forming a film to a uniform thickness within a top surface of a substrate and on a surface of a pattern of the substrate. As one of techniques satisfying such a need, a method of forming a film on a substrate using a plurality of sources has been introduced. In particular, according to this method, for example, a conformal film having high step coverage may be formed when a DRAM capacitor electrode having a high aspect ratio and the like is formed.

In a film-forming method of forming a film by supplying a first gas and a second gas, the first gas and the second gas may unintentionally react with each other to prevent desired film characteristics from being achieved, thereby degrading characteristics of a semiconductor device.

### SUMMARY

It is an object of the present invention to provide a substrate processing apparatus, a gas dispersion unit, a method of manufacturing a semiconductor device and a non-transitory computer-readable recording medium which are capable of improving characteristics of a film formed on a substrate.

According to one aspect of the present invention, there is provided a substrate processing apparatus including a process chamber configured to process a substrate; a substrate placement unit configured to have the substrate placed thereon; and a gas dispersion unit including a first supply region facing the substrate and including a first gas dispersion hole configured to supply a first gas and a second gas dispersion hole configured to supply a second gas; and a second supply region facing a portion of a surface of the substrate placement unit outer than a portion of the surface of the substrate placement unit occupied by the substrate and including a third gas dispersion hole having a diameter greater than that of the second gas dispersion hole and configured to supply the second gas.

### BRIEF DESCRIPTION OF THE DRAWINGS

FIG. 1 is a schematic configuration diagram of a substrate processing apparatus according to a first embodiment of the present invention.

FIG. 2 illustrates a surface of a shower head facing a substrate according to the first embodiment of the present invention.

FIG. 3 is a schematic configuration diagram of a gas supply system of a substrate processing apparatus according to the first embodiment of the present invention.

FIG. 4 is a schematic configuration diagram of a controller of a substrate processing apparatus according to the first embodiment of the present invention.

FIG. 5 is a flowchart of a substrate processing process according to the first embodiment of the present invention.

FIG. 6 is a diagram illustrating a sequence of supplying a gas to a shower head according to the first embodiment of the present invention.

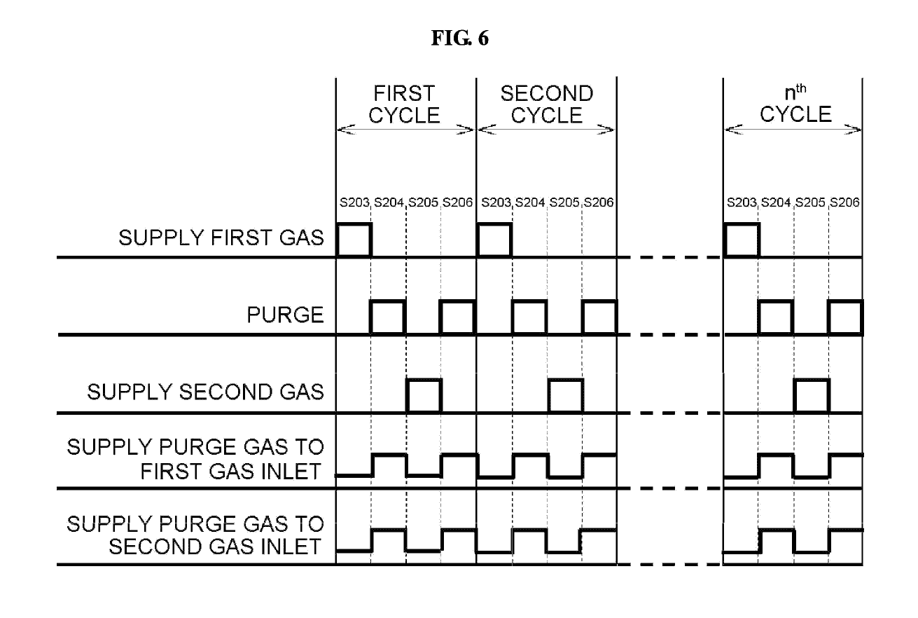

FIG. 7 illustrates a surface of a shower head facing a substrate according to a second embodiment of the present invention.

FIG. 8 illustrates a surface of a shower head facing a substrate according to a third embodiment of the present invention.

### DETAILED DESCRIPTION

### First Embodiment

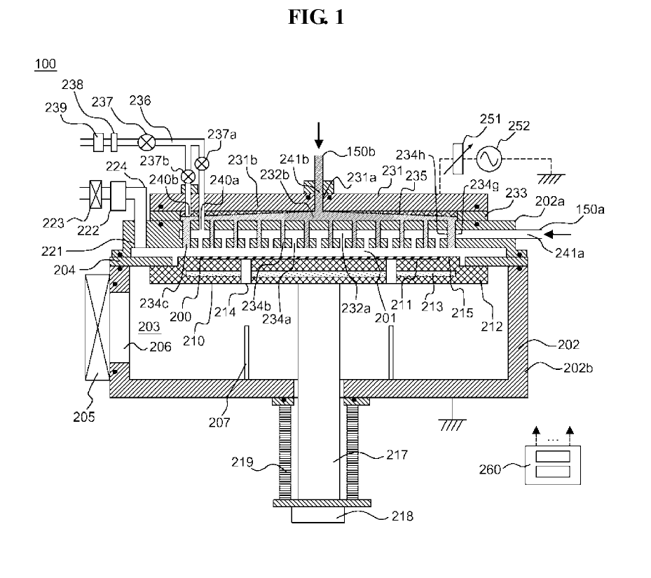

A first embodiment of the present invention will be described with reference to FIG. 1 below.

### (1) Structure of Substrate Processing Apparatus

First, a substrate processing apparatus according to the first embodiment will be described.

The substrate processing apparatus 100 according to the present embodiment will be described below. The substrate processing apparatus 100 is a unit configured to form a high-k insulating film and is configured as a single-wafer type substrate processing apparatus as illustrated in FIG. 1. A method of manufacturing a semiconductor device as described above is performed by the substrate processing apparatus 100.

As illustrated in FIG. 1, the substrate processing apparatus 100 includes a process vessel 202. The process vessel 202 comprises, for example, a flat airtight container having a circular cross-section. In addition, the process vessel 202 is formed of a metal material, e.g., aluminum (Al) or stainless steel (steel-use-stainless (SUS)), or quartz. In the process vessel 202, a process space 201 (process chamber) for processing a wafer 200 (e.g., a silicon wafer, etc.) serving as a substrate and a transfer space 203 are formed. The process vessel 202 includes an upper process vessel 202a and a lower process vessel 202b. A partition plate 204 is installed between the upper process vessel 202a and the lower process vessel 202b. A space surrounded by the upper process vessel 202a and located above the partition plate 204 will be referred to as the process space (which may also be referred to as the process chamber) 201. A space surrounded by the lower process vessel 202b and located below the partition plate 204 will be referred to as the transfer space 203.

A substrate loading exit 206 is installed at a side of the lower process vessel 202b to be adjacent to a gate valve 205. The wafer 200 is moved between transfer chambers (not shown) via the substrate loading exit 206. A plurality of lift pins 207 are installed on a bottom portion of the lower process vessel 202b. In addition, the lower process vessel 202b is earthed.

In the process chamber 201, a substrate support 210 is installed to support the wafer 200. The substrate support 210 includes a substrate placement unit 212 having a substrate placement surface 211 for placing the wafer 200 thereon and an outer circumferential surface 215. A heater 213 serving as a heating unit is preferably installed. By installing the heating unit, a substrate may be heated to improve the quality of a film formed on the substrate. A plurality of through-holes 214 through which the plurality of lift pins 207 pass may be formed in locations on the substrate placement unit 212 corresponding to the plurality of lift pins 207. In addition, a height of the substrate placement surface 211 formed on the substrate placement unit 212 may be lower than that of the outer circumferential surface 215 by a length corresponding to a thickness of the wafer 200. By configuring the substrate placement surface 211, the difference between heights of a top surface of the wafer 200 and the outer circumferential surface 215 of the substrate placement unit 212 may be reduced to suppress a turbulent flow of a gas caused by the difference between the heights of the top surface of the wafer 200 and the outer circumferential surface 215 of the substrate placement unit 212. However, when uniform processing of the wafer 200 is not influenced by the turbulent flow of a gas, a height of the outer circumferential surface 215 may be set to equal to or greater than that of the substrate placement surface 211 on the same plane.

The substrate placement unit 212 is supported by a shaft 217. The shaft 217 passes through a lower portion of the process vessel 202, and is connected to an elevating mechanism 218 outside the process vessel 202. The wafer 200 placed on the substrate placement surface 211 may be moved upward or downward by operating the elevating mechanism 218 to move the shaft 217 and the substrate placement unit 212 upward or downward. In addition, the vicinity of a lower end portion of the shaft 217 is covered with a bellows 219, and the inside of the process chamber 201 is maintained in an air-tight state.

The substrate placement unit 212 is moved downward such that the substrate placement surface 211 is located at the substrate loading exit 206 (i.e., a wafer transfer position) so as to transfer the wafer 200, and is moved upward such that the wafer 200 is located at a processing position (i.e., a wafer processing position) in the process chamber 201 so as to process the wafer 200 as illustrated in FIG. 1.

Specifically, when the substrate placement unit 212 is moved downward to the wafer transfer position, upper end portions of the lift pins 207 protrude from an upper surface of the substrate placement surface 211 to support the wafer 200 from below. When the substrate placement unit 212 is moved upward to the wafer processing position, the lift pins 207 are buried downward from the upper surface of the substrate placement surface 211 so that the wafer 200 may be supported by the substrate placement surface 211 from below. The lift pins 207 directly contact the wafer 200 and are thus preferably formed of, for example, quartz or alumina. In addition, an elevating mechanism may be installed at the plurality of lift pins 207 to relatively move the substrate placement unit 212 and the plurality of lift pins 207 with one another.

### [Exhaust System]

An exhaust port 221 serving as a first exhaust unit for exhausting an atmosphere in the process chamber 201 is installed on a top surface of an inner wall of the process chamber 201 (the upper process vessel 202a). An exhaust pipe 224 is connected as a first exhaust pipe to the exhaust port 221. A pressure adjusting unit 222 (such as an auto-pressure controller (APC)) configured to control the inside of the process chamber 201 to have a predetermined pressure and a vacuum pump 223 are sequentially connected in series to the exhaust pipe 224. The first exhaust unit (exhaust line) mainly includes the exhaust port 221, the exhaust pipe 224 and the pressure adjusting unit 222. The first exhaust unit may further include the vacuum pump 223.

A shower head exhaust hole 240a serving as a second exhaust unit for exhausting an atmosphere in a first buffer space 232a is installed on a top surface of an inner wall of the first buffer space 232a. An exhaust pipe 236 is connected as a second exhaust pipe to the shower head exhaust hole 240a. A valve 237a, a pressure adjusting unit 238 (such as an APC) configured to control the inside of the first buffer space 232a to have a predetermined pressure, and a vacuum pump 239 are sequentially connected in series to the exhaust pipe 236. The second exhaust unit (exhaust line) mainly includes the shower head exhaust hole 240a, the valve 237a, the exhaust pipe 236 and the pressure adjusting unit 238. The second exhaust unit may further include the vacuum pump 239. In addition, the exhaust pipe 236 may be connected to the vacuum pump 223 without installing the vacuum pump 239.

A shower head exhaust hole 240b serving as a third exhaust unit for exhausting an atmosphere in a second buffer space 232b is installed on a top surface of an inner wall of the second buffer space 232b. The exhaust pipe 236 is connected as a third exhaust pipe to the shower head exhaust hole 240b. A valve 237b, the pressure adjusting unit 238 (such as an APC) configured to control the inside of the second buffer space 232b to have a predetermined pressure, and the vacuum pump 239 are sequentially connected in series to the exhaust pipe 236. The third exhaust unit (exhaust line) mainly includes the shower head exhaust hole 240b, the valve 237b, the exhaust pipe 236 and the pressure adjusting unit 238. The third exhaust unit may further include the vacuum pump 239. Here, a case in which the exhaust pipe 236, the pressure adjusting unit 238 and the vacuum pump 239 are shared with the second exhaust unit is illustrated in FIG. 1. In addition, the exhaust pipe 236 may be connected to the vacuum pump 223 without installing the vacuum pump 239.

### [Gas Inlet]

A first gas inlet 241a is formed in a sidewall of the upper process vessel 202a to supply various gases into the process chamber 201. In addition, a second gas inlet 241b is formed in a top surface (a ceiling wall) of a shower head 234 installed above the process chamber 201 to supply various gases into the process chamber 201. The structures of various gas supply units connected to the first gas inlet 241a which is a first gas introduction unit and the second gas inlet which is a second gas introduction unit will be described below. Otherwise, the first gas inlet 241a to which a first gas is supplied may be installed in the top surface (ceiling wall) of the shower head 234 so that the first gas may be supplied via a center of the first buffer space 232a. By supplying the first gas via the center of the first buffer space 232a, a gas may uniformly flow in the first buffer space 232a from the center of the first buffer space 232a to an outer circumference thereof, thereby controlling the amount of a gas supplied onto the wafer 200 to a constant level.

### [Gas Dispersion Unit]

The shower head 234 includes the first buffer chamber 232a (first buffer space), first dispersion holes 234a, the second buffer chamber 232b (second buffer space) and the second dispersion hole 234b. The shower head 234 is installed between the second gas inlet 241b and the process chamber 201. The first gas supplied via the first gas inlet 241a is supplied into the first buffer space 232a (first dispersion unit) of the shower head 234. The second gas inlet 241b is connected to a lid 231 of the shower head 234. The second gas supplied via the second gas inlet 241b is supplied into the second buffer space 232b (second dispersion unit) of the shower head 234 via a hole 231a formed in the lid 231. The shower head 234 is formed of, for example, quartz, stainless steel, aluminum, etc.

In addition, the lid 231 of the shower head 234 may be formed of a conductive metal to serve as an activation unit (excitation unit) for exciting a gas present in the first buffer space 232a, the second buffer space 232b or the process chamber 201. In this case, an insulating block 233 may be installed between the lid 231 and the upper process vessel 202a to insulate the lid 231 and the upper process vessel 202a from each other. A matching device 251 and a high-frequency power source 252 may be connected to an electrode (the lid 231) serving as an activation unit so as to supply electromagnetic waves (high-frequency power or microwaves).

The shower head 234 has a function of dispersing a gas, which is supplied via the first gas inlet 241a and the second gas inlet 241b, among the first buffer space 232a, the second buffer space 232b and the process chamber 201. The shower head 234 includes a first-first supply region and a second-first supply region that constitute a first supply region 234e. The first-first supply region includes the first dispersion holes 234a, and the second-first supply region includes a plurality of second dispersion holes 234b. A second supply region 234f is formed along an outer circumference of the first supply region 234e. The second supply region 234f includes a plurality of third dispersion holes 234c. The first gas is supplied into the process space 201 from the first dispersion holes 234a via the first buffer space 232a. The second gas is supplied into the process space 201 from the second dispersion holes 234b via the second buffer space 232b. In addition, the second gas is supplied into the process space 201 from the third dispersion holes 234c via the second buffer space 232b. The first and second dispersion holes 234a and 234b face the substrate placement surface 211. Thus, gases supplied into the process space 201 via the first and second dispersion holes 234a and 234b are supplied mainly onto the wafer 200. The third dispersion holes 234c are disposed outside an outer circumference of the wafer 200 and to face the outer circumferential surface 215 of the substrate placement unit 212. Thus, a gas supplied into the process space 201 via the third dispersion holes 234c is supplied mainly onto the outer circumferential surface 215 and exhausted via an exhaust unit.

A gas guide 235 may be installed to form flow of the second gas supplied into the second buffer space 232b. The gas guide 235 has a conical shape, the diameter of which increases in a direction of the diameter of the wafer 200 with respect to the hole 231a. A horizontal diameter of a lower end of the gas guide 235 extends toward the outer circumference of the wafer 200 more than end portions of the first and second dispersion holes 234a and 234b.

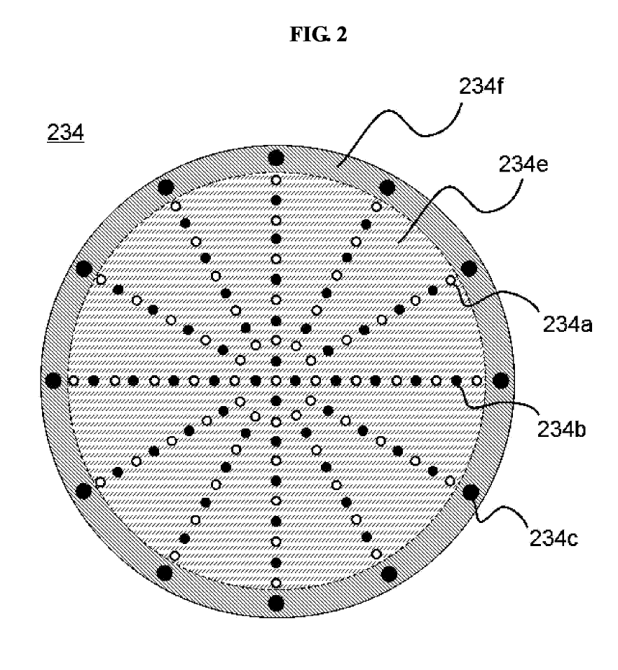

FIG. 2 illustrates the shower head 234 viewed from a side of the wafer 200. In FIG. 2, some gas supply holes are not illustrated for convenience of explanation. As illustrated in FIG. 2, holes having the same diameters as the first and second gas dispersion holes 234a and 234b are installed to be arranged regularly. The diameter, shape and position of each of the holes may be changed according to a substrate processing method or the type of a gas to be used.

The gas dispersion unit includes at least the first supply region 234e and the second supply region 234f.

### [Supply System]

A first gas supply pipe 150a is connected to the gas inlet 241a which is a first gas introduction unit connected to the upper process vessel 202a. A second gas supply pipe 150b is connected to the gas inlet 241b which is a second gas introduction unit connected to the lid 231 of the shower head 234. A source gas and a purge gas which will be described below are supplied via the first gas supply pipe 150a, and a reactive gas and a purge gas which will be described below are supplied via the second gas supply pipe 150b.

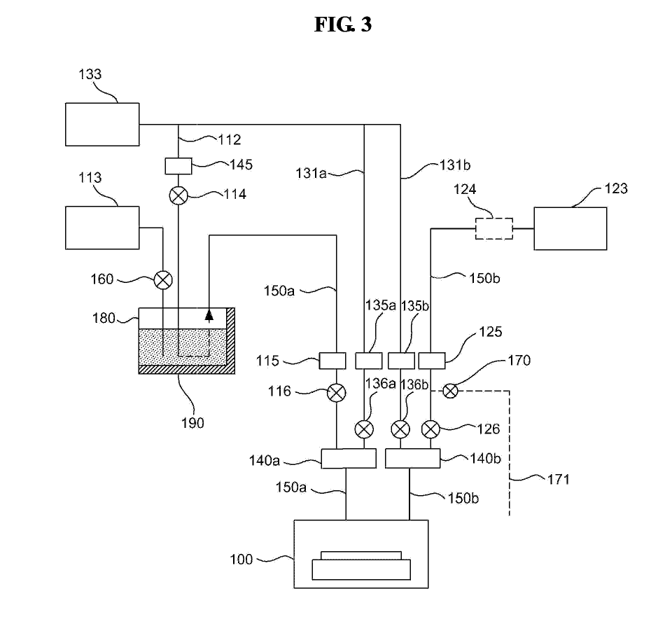

FIG. 3 is a schematic configuration diagram of a first gas supply unit, second gas supply unit and a purge gas supply unit.

As illustrated in FIG. 3, a first gas supply pipe assembly unit 140a is connected to the first gas supply pipe 150a. A second gas supply pipe assembly unit 140b is connected to the second gas supply pipe 150b. The first gas supply pipe 150a and a purge gas supply unit 131a are connected to the first gas supply pipe assembly unit 140a. The second gas supply pipe 150b and a purge gas supply unit 131b are connected to the second gas supply pipe assembly unit 140b.

### [First Gas Supply Unit]

A first gas supply system includes a first gas source valve 160, a vaporizer 180, the first gas supply pipe 150a, a mass flow controller (MFC) 115, a valve 116 and a vaporizer residual value measurement unit 190. The first gas supply system may further include a first gas source 113. The vaporizer 180 is configured to vaporize a gas by supplying a carrier gas to a gas source that is in a liquid state and causing the gas source to bubble.

The carrier gas is supplied via a gas supply pipe 112 connected to a purge gas source 133. A flow rate of the carrier gas is adjusted by an MFC 145 installed at the gas supply pipe 112 and then the carrier gas is supplied to the vaporizer 180 via a gas valve 114. The vaporizer residual value measurement unit 190 is configured to measure the amount of a source gas based on the weight of a gas source present in the vaporizer 180, the height of a liquid surface, etc. A degree of opening or closing of the gas valve 114 is controlled to control the amount of a gas source in the vaporizer 180 to be equal to a predetermined level, based on a result of measuring the amount of the source gas by the vaporizer residual value measurement unit 190.

### [Second Gas Supply Unit]

At the second gas supply unit, the second gas supply pipe 150b, an MFC 125 and a valve 126 are installed. The second gas supply unit may further include a second gas source 123. In addition, a remote plasma unit (RPU) 124 may be installed to activate the second gas. In addition, a vent valve 170 and a vent pipe 171 may be installed to exhaust an inert reactive gas remaining in the second gas supply pipe 150b.

### [Purge Gas Supply Unit]

At the purge gas supply unit, the gas supply pipes 112, 131a and 131b, MFCs 145, 135a and 135b, and valves 114, 136a and 136b are installed. The purge gas supply unit may further include the purge gas source 133.

### [Control Unit]

As illustrated in FIG. 1, the substrate processing apparatus 100 includes a controller 260 configured to control operations of various components of the substrate processing apparatus 100.

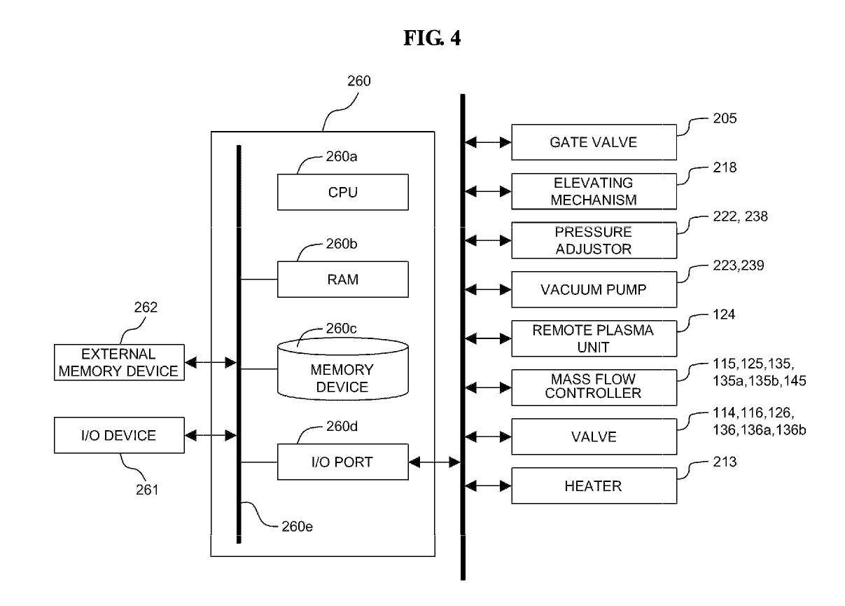

The controller 260 is schematically illustrated in FIG. 4. The controller 260 which is a control unit (control means) may comprise a computer that includes a central processing unit (CPU) 260a, a random access memory (RAM) 260b, a memory device 260c and an input/output (I/O) port 260d. The RAM 260b, the memory device 260c and the I/O port 260d are configured to exchange data with the CPU 260a via an internal bus 260e. The controller 260 is configured to be accessible by an I/O device 261 embodied, for example, as a touch panel or an external memory device 262.

The memory device 260c includes, for example, a flash memory, a hard disk drive (HDD), etc. In the memory device 260c, a control program for controlling an operation of the substrate processing apparatus 100, a program recipe including an order or conditions of substrate processing which will be described below, etc. is stored to be readable. The program recipe is a combination of sequences of a substrate processing process which will be described below to obtain a desired result when the sequences are performed by the controller 260, and acts as a program. Hereinafter, the program recipe, the control program, etc. will also be referred to together simply as a “program.” In addition, when the term “program” is used in the present disclosure, it should be understood as including only the program recipe, only the control program, or both of the program recipe and the control program. The RAM 260b is configured as a memory area (work area) in which a program or data read by the CPU 260a is temporarily stored.

The I/O port 260d is connected to the gate valve 205, the elevating mechanism 218, the heater 213, the pressure adjusting units 222 and 238, the vacuum pumps 223 and 239, the vaporizer 180, the vaporizer residual value measurement unit 190, etc. In addition, the I/O port 260d may be connected to the MFCs 115, 125, 135, 135a, 135b and 145, the valves 237, 237a and 237b, the gas valves 114, 116, 126, 136, 136a and 136b, the first gas source valve 160, the vent valve 170, the RPU 124, the matching device 251, the high-frequency power source 252, a transport robot 105, a standby transfer unit 102, a load lock unit 103, etc. which will be described below.

The CPU 260a is configured to read a process recipe from the memory device 260c according to a manipulation command, etc. which is input via the I/O device 261 while reading and executing a control program stored in the memory device 260c. In addition, based on the read process recipe, the CPU 260a is configured to control measurement of the amount of a residual source gas by the vaporizer residual value measurement unit 190; control opening/closing of the gate valve 205; control upward/downward movement of the elevating mechanism 218; control supply of power to the heater 213; control pressure adjustment by the pressure adjusting units 222 and 238; control power of the vacuum pumps 223 and 239; control activation of a gas by the RPU 124; control a flow rate of a gas by the MFCs 115, 125, 135, 135a and 135b; control opening/closing of the valves 237, 237a and 237b, the gas valves 114, 116, 126, 136, 136a and 136b, the first gas source valve 160 and the vent valve 170; control a power matching operation by the matching device 251; control power of the high-frequency power source 252, etc.

The controller 260 is not limited to a dedicated computer and may include a general-purpose computer. For example, the controller 260 according to the present embodiment may be provided with the external memory device 262 storing a program as described above, e.g., a magnetic tape, a magnetic disk (e.g., a flexible disk, a hard disk, etc.), an optical disc (e.g., a compact disc (CD), a digital versatile disc (DVD), etc.), a magneto-optical (MO) disc or a semiconductor memory (e.g., a Universal Serial Bus (USB) memory, a memory card, etc.), and then installing the program in a general-purpose computer using the external memory device 262. However, a means for supplying the program to a computer is not limited to using the external memory device 262. For example, the program may be supplied to a computer using a communication means, e.g., the Internet or an exclusive line, without using the external memory device 262. The memory device 260c or the external memory device 262 may include a non-transitory computer-readable recording medium. Hereinafter, the memory device 260c or the external memory device 262 may also be referred to together simply as a “recording medium.” When the term “recording medium” is used in the present disclosure, it may be understood as only the memory device 260c, only the external memory device 262, or both of the memory device 260c and the external memory device 262.

### (2) Substrate Processing Process

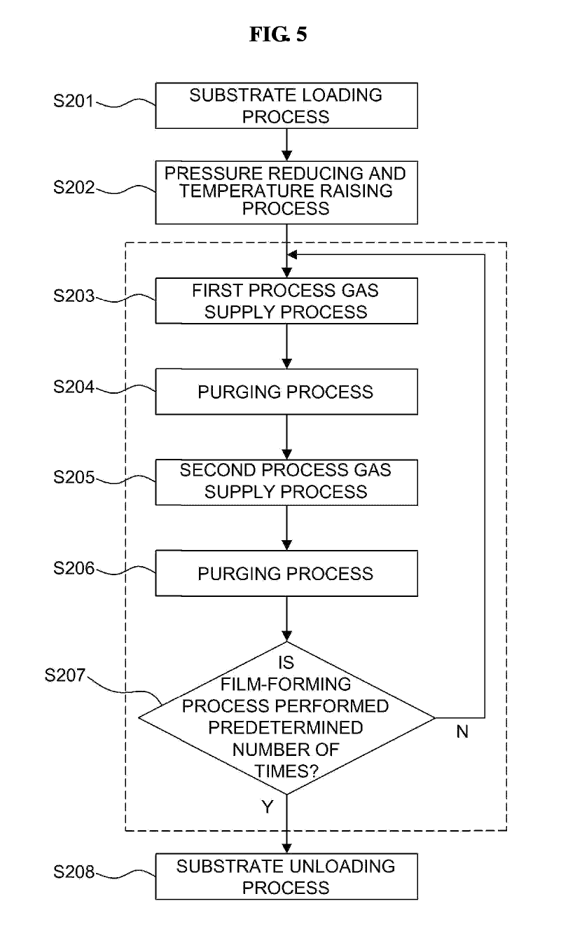

Next, an example of a sequence of forming a titanium nitride (TiN) film as a transition metal nitride film which is a conductive film, e.g., a metal-containing film, on a substrate using a process furnace of the substrate processing apparatus 100 be described as a process included in a process of manufacturing a semiconductor device with reference to FIG. 5 below. In the following description, operations of various components of the substrate processing apparatus 100 are controlled by the controller 260.

When the term ‘wafer’ is used in the present disclosure, it should be understood as either the wafer itself, or both the wafer and a stacked structure (assembly) including a layer/film formed on the wafer (i.e., the wafer and the layer/film formed thereon may also be referred to collectively as the ‘wafer’). In addition, when the expression ‘surface of the wafer’ is used in the present disclosure, it should be understood as either a surface (exposed surface) of the wafer itself or a surface of a layer/film formed on the wafer, i.e., an uppermost surface of the wafer as a stacked structure.

Thus, in the present disclosure, the expression ‘specific gas is supplied onto a wafer’ should be understood to mean that the specific gas is directly supplied onto a surface (exposed surface) of the wafer or that the specific gas is supplied onto a layer/film on the wafer. In addition, this expression may be understood to mean that a layer or film is formed on a layer or film formed on a wafer, i.e., on the uppermost surface of the wafer as a stacked structure.

In the present disclosure, the term ‘substrate’ has the same meaning as the term ‘wafer.’ Thus, the term ‘wafer’ may be used interchangeably with the term ‘substrate.’

A substrate processing process will be described below.

### [Substrate Loading Process (S201)]

First, the wafer 200 is loaded into the process chamber 201 when a film-forming process is to be performed. Specifically, the substrate support 210 is moved downward by the elevating mechanism 218 to cause the plurality of lift pins 207 to protrude from the through-holes 214 toward a top surface of the substrate support 210. In addition, after the inside of the process chamber 201 is adjusted to have a predetermined pressure, the gate valve 205 is opened and the wafer 200 is placed on the plurality of lift pins 207 via the gate valve 205. After the wafer 200 is placed on the plurality of lift pins 207, the substrate support 210 is moved upward to a predetermined position by the elevating mechanism 218 so as to cause the wafer 200 to be placed on the substrate support 210 from the plurality of lift pins 207.

### [Pressure Reducing and Temperature Raising Process (S202)]

Then, the inside of the process chamber 201 is exhausted via the exhaust pipe 224 such that the inside of the process chamber 201 has a predetermined pressure (degree of vacuum). In this case, a degree of openness of the pressure adjusting unit 222, e.g., an APC valve, is feedback controlled based on a pressure sensed by a pressure sensor (not shown). In addition, the amount of electric power to be supplied to the heater 213 is feedback controlled such that the inside of the process chamber 201 has a predetermined temperature, based on a temperature sensed by a temperature sensor (not shown). Specifically, the substrate support 210 is heated beforehand by the heater 213 and is left for a predetermined time when the temperature of the wafer 200 or the substrate support 210 becomes stable. When degassing occurs from moisture or members present in the process chamber 201 while the substrate support 210 is left for the predetermined time, vacuum exhausting or purging using N₂ gas may be performed. Accordingly, a preparation for the film-forming process is completed. In addition, when the inside of the process chamber 201 is exhausted to the predetermined pressure, the inside of the process chamber 201 may be vacuum-exhausted to a degree of vacuum that the process chamber 201 can reach in one cycle.

### [Film-Forming Process (S301)]

Next, a method of forming a TiN film on the wafer 200 will be described. The film-forming process (S301) will be described in detail with reference to FIG. 5.

After the wafer 200 is placed on the substrate support 210 and an atmosphere in the process chamber 201 is stabilized, steps of the process illustrated in FIG. 5 (i.e., S203 to S207) are performed.

### [First Gas Supply Process (S203)]

In the first gas supply process (S203), titanium tetrachloride (TiCl₄) gas is supplied as a first gas (source gas) into the process chamber 201 using the first gas supply system. Specifically, the gas source valve 160 is opened to supply TiCl₄ to the vaporizer 180. In this case, the gas valve 114 is opened to supply a carrier gas, the flow rate of which is adjusted by the MFC 145, to the vaporizer 180, and the supplied TiCl₄ is changed into a gas, i.e., TiCl₄ gas, by causing it to bubble. Otherwise, changing of TiCl₄ into a gas may be started before the substrate loading process (S201) is performed. A flow rate of the TiCl₄ gas is adjusted by the MFC 115 and the flow-rate-adjusted TiCl₄ gas is supplied to the substrate processing apparatus 100. The flow-rate-adjusted TiCl₄ gas passes through the first buffer space 232a and is then supplied into the process chamber 201 which is in a pressure-reduced state via the first dispersion hole 234a of the shower head 234. In addition, the inside of the process chamber 201 is continuously exhausted using the exhaust system to control pressure in the process chamber 201 to be in a predetermined pressure range (first pressure). In this case, the TiCl₄ gas supplied onto the wafer 200 is supplied into the process chamber 201 at a predetermined pressure (first pressure, e.g., a range of 100 Pa to 20,000 Pa). The TiCl₄ gas is supplied onto the wafer 200 as described above. When the TiCl₄ gas is supplied onto the wafer 200, a titanium (Ti)-containing layer is formed on the wafer 200.

### [Purging Process (S204)]

After the Ti-containing layer is formed on the wafer 200, the gate valve 116 of the first gas supply pipe 150a is closed to stop the supply of the TiCl₄ gas. The purging process (S204) is performed by stopping the supply of the source gas, i.e., the supply of the TiCl₄ gas, and exhausting the source gas from the process chamber 201 or the first buffer space 232a using the first exhaust unit.

The purging process (S204) may be set to include not only simply exhausting (vacuum-sucking) and discharging a gas but also supplying an inert gas to push out a residual gas. In addition, the vacuum-sucking of the gas and the supplying of the inert gas may be performed in combination. Otherwise, the vacuum-sucking of the gas and the supplying of the inert gas may be performed alternately.

In this case, the valve 237a of the exhaust pipe 236 may be opened to exhaust a gas present in the first buffer space 232a through the exhaust pump 239 via the exhaust pipe 236. In this case, the exhaust pump 239 is operated beforehand and is continuously operated at least until the substrate processing process ends. In addition, pressures (exhaust conductances) in the exhaust pipe 236 and the first buffer space 232a are controlled using the pressure adjusting unit 238 during the exhausting of the gas. The pressure adjusting unit 238 and the vacuum pump 239 may be controlled such that an exhaust conductance in the first buffer space 232a using the first exhaust system is higher than a conductance of the exhaust pump 224 via the process chamber 201. By controlling the pressure adjusting unit 238 and the vacuum pump 239 as described above, the flow of a gas from the first gas inlet 241a which is one end portion of the first buffer space 232a toward the shower head exhaust hole 240a which is another end portion of the first buffer space 232a is formed. Thus, a gas attached to a wall of the first buffer space 232a or a gas floating in the first buffer space 232a may be exhausted from the first exhaust system without entering the process chamber 201. In addition, pressures (conductances) in the first buffer space 232a and the process chamber 201 may be adjusted to suppress a gas from flowing backward from the process chamber 201 into the first buffer space 232a.

In addition, in the purging process (S204), a gas present in the process space 201 is exhausted through the vacuum pump 223 by continuously operating the vacuum pump 223. In addition, the pressure adjusting unit 222 may be controlled such that an exhaust conductance from the process chamber 201 using the vacuum pump 223 is higher than an exhaust conductance from the first buffer space 232a. By controlling the pressure adjusting unit 222 as described above, the flow of a gas toward the second exhaust unit via the process chamber 201 is formed to exhaust a gas remaining in the process chamber 201. Here, an inert gas may be more reliably supplied onto the wafer 200 when the inert gas is supplied by opening the gas valve 136a and controlling the MFC 135a, thereby increasing the efficiency of removing a residual gas from the wafer 200.

After a predetermined time elapses, the valve 136a is closed to stop the supply of the inert gas and the valve 237a is closed to block between the first buffer space 232a and the vacuum pump 239.

More preferably, after the predetermined time elapses, the valve 237a is closed while continuously operating the vacuum pump 223. In this case, the flow of a gas toward the second exhaust system via the process chamber 201 is not influenced by the first exhaust system and the inert gas may be more reliably supplied onto the wafer 200, thereby greatly increasing the efficiency of removing the residual gas from the wafer 200.

In addition, purging of the inside of the process chamber 201 may be understood to include not only simply discharging a gas by vacuum-sucking the gas but also supplying an inert gas to push out a residual gas. Thus, in the purging process (S204), a residual gas may be discharged by supplying an inert gas into the first buffer space 232a to push out the residual gas. In addition, the vacuum-sucking of the gas and the supplying of the inert gas may be performed in combination. Otherwise, the vacuum-sucking of the gas and the supplying of the inert gas may be performed alternately.

In this case, the flow rate of N₂ gas to be supplied into the process chamber 201 need not be high. For example, the inside of the process chamber 201 may be purged without causing a subsequent process to be negatively influenced by the N₂ gas by supplying an amount of the N₂ gas corresponding to the capacity of the process chamber 201. When the inside of the process chamber 201 is not completely purged, a purge time may be reduced to improve the throughput. Furthermore, the consumption of the N₂ gas may be reduced to a necessary minimum level.

In this case, the temperature of the heater 213 is set to be maintained constant in a range from 200° C. to 750° C., preferably, a range from 300° C. to 600° C., and more preferably, a range of 300° C. to 550° C., similar to when a source gas is supplied to the wafer 200. A supply flow rate of N₂ gas supplied as a purge gas using each of the inert gas supply systems is set to be, for example, in a range of 100 sccm to 20,000 sccm. As the purge gas, a rare gas, such as Ar gas, He gas, Ne gas, Xe gas, etc., may be used in addition to N₂ gas.

### [Second Gas Supply Process (S205)]

After the purging process (S204) is performed using the first gas, the valve 126 is opened to supply ammonia gas (NH₃) as a second gas (reactive gas) into the process chamber 201 via the gas inlet 241b, the second buffer space 232b and the dispersion holes 234b. Since the ammonia gas (NH₃) is supplied into the process chamber 201 via the second buffer space 232b and the dispersion holes 234b, a gas may be uniformly supplied onto the wafer 200. Thus, a film may be formed to a uniform thickness. In addition, the second gas activated via the RPU 124 as an activating unit (exciting unit) may be supplied into the process chamber 201.

In this case, the NH₃ gas is adjusted to have a predetermined flow rate by the MFC controller 125. In addition, the supply flow rate of the NH₃ gas is, for example, in a range of 100 sccm to 10,000 sccm. In addition, a pressure in the second buffer space 232b is set to be in a predetermined range of pressure by appropriately controlling the pressure adjusting unit 238. While the NH₃ gas flows though the inside of the RPU 124, the RPU 124 is ‘on’ (i.e., the RPU 124 is powered on) to activate (excite) the NH₃ gas.

When the NH₃ gas is supplied to a Ti-containing layer formed on the wafer 200, the Ti-containing layer is changed into, for example, a modified layer containing titanium. In addition, by installing the RPU 124 and supplying activated NH₃ gas to the wafer 200, more modified layers may be formed.

The modified layer is formed to have a predetermined thickness and distribution and an invasion depth of a predetermined nitrogen component or the like into the Ti-containing layer, based on, for example, the pressure in the process chamber 201, the flow rate of the NH₃ gas, the temperature of the wafer 200, the amount of power supplied to the RPU 124, etc.

After a predetermined time elapses, the valve 126 is closed to stop the supply of the NH₃ gas.

### [Purging Process (S206)]

By stopping the supply of the NH₃ gas, a source gas present in the process chamber 201 or the first buffer space 232a is exhausted using the first exhaust unit to perform a purging process (S206).

The purging process (S206) may be set to include not only simply discharging a gas by exhausting (vacuum-sucking) the gas but also discharging a residual gas by supplying an inert gas and pushing out the residual gas. In addition, the vacuum-sucking of the gas and the supplying of the inert gas may be performed in combination. Otherwise, the vacuum-sucking of the gas and the supplying of the inert gas may be performed alternately.

In addition, the valve 237a may be opened to exhaust a gas present in the second buffer space 232b through the vacuum pump 239 via the exhaust pipe 236. In addition, pressures (exhaust conductances) in the exhaust pipe 236 and the second buffer space 232b) are controlled using the pressure adjusting unit 238 during the exhausting of the gas. The pressure adjusting unit 238 and the vacuum pump 239 may be controlled such that an exhaust conductance in the second buffer space 232b using the first exhaust system is higher than a conductance of the vacuum pump 223 via the process chamber 201. By controlling the pressure adjusting unit 238 and the vacuum pump 239 as described above, the flow of a gas from the center of the second buffer space 232b toward the shower head exhaust hole 240b is formed. In addition, a gas attached to a wall of the second buffer space 232b or a gas flowing in the second buffer space 232b may be exhausted from the third exhaust system without entering the process chamber 201. In addition, pressures (exhaust conductances) in the second buffer space 232b and the process chamber 201 may be adjusted to suppress a gas from flowing backward from the process chamber 201 into the second buffer space 232b.

In addition, in the purging process (S206), a gas present in the process space 201 is exhausted through the vacuum pump 223 by continuously operating the vacuum pump 223. In addition, the pressure adjusting unit 222 may be controlled such that an exhaust conductance from the process chamber 201 to the vacuum pump 223 is higher than an exhaust conductance from the process chamber 201 to the second buffer space 232b. By controlling the pressure adjusting unit 222 as described above, the flow of a gas toward the third exhaust system via the process chamber 201 may be formed to exhaust a gas remaining in the process chamber 201. Here, the gas valve 136b may be opened to reliably supply the inert gas to the wafer 200 by controlling the MFC 135b, thereby increasing the efficiency of removing a residual gas from the wafer 200.

After a predetermined time elapses, the gas valve 136b is closed to stop the supply of the inert gas and the valve 237b is closed to block between the second buffer space 232b and the vacuum pump 239.

More preferably, after the predetermined time elapses, the valve 237a is closed while continuously operating the vacuum pump 223. In this case, the flow of a gas toward the third exhaust system via the process chamber 201 is not influenced by the first exhaust system and the inert gas may be more reliably supplied to the wafer 200, thereby greatly increasing the efficiency of removing a residual gas from the wafer 200.

In addition, purging of the inside of the process chamber 201 may be understood to include not only simply discharging a gas by vacuum-sucking the gas but also supplying an inert gas to push out the gas. Thus, in the purging process (S206), a residual gas may be discharged by supplying an inert gas into the second buffer space 232b to push out the residual gas. In addition, the vacuum-sucking of the gas and the supplying of the inert gas may be performed in combination. Otherwise, the vacuum-sucking of the gas and the supplying of the inert gas may be performed alternately.

In this case, the flow rate of N₂ gas to be supplied into the process chamber 201 need not be high. For example, the inside of the process chamber 201 may be purged without causing a subsequent process to be negatively influenced by the N₂ gas by supplying an amount of the N₂ gas corresponding to the capacity of the process chamber 201. When the inside of the process chamber 201 is not completely purged, a purge time may be reduced to improve the throughput. Furthermore, the consumption of the N₂ gas may be reduced to a necessary minimum level.

In this case, the temperature of the heater 213 is set to be maintained constant in a range from 200° C. to 750° C., preferably, a range from 300° C. to 600° C., and more preferably, a range of 300° C. to 550° C., similar to when a source gas is supplied to the wafer 200. A supply flow rate of N₂ gas supplied as a purge gas using each of the inert gas supply systems is set to be, for example, in a range of 100 sccm to 20,000 sccm. As the purge gas, a rare gas, such as Ar gas, He gas, Ne gas, Xe gas, etc., may be used in addition to N₂ gas.

### [Process (S207) of Determining the Number of Times the Film-Forming Process is Performed]

After the purging process (S206) ends, the controller 260 determines whether the film-forming process (S301) including steps S203 to S206 has been performed a predetermined number of times (n times). That is, it is determined whether a film is formed on the wafer 200 to a desired thickness. By performing a cycle including steps S203 to S206 described above at least once (step S207), a conductive film including titanium and nitrogen, i.e., a TiN film, may be formed on the wafer 200 to a predetermined thickness. The above cycle is preferably repeatedly performed. Thus, a TiN film is formed on the wafer 200 to the predetermined thickness.

When it is determined that the cycle has not been performed the predetermined number of times (when it is determined as ‘No’), the cycle including steps S203 to S206 is repeatedly performed. When it is determined that the cycle has been performed the predetermined number of times (when it is determined as ‘yes’), the film-forming process (S301) ends and a substrate unloading process (S208) is performed.

### [Substrate Unloading Process (S208)]

After the film-forming process (S301) ends, the substrate support 210 is moved downward by the elevating mechanism 218 to cause the plurality of lift pins 207 to protrude from the through-holes 214 toward the top surface of the substrate support 210. After the inside of the process chamber 201 is adjusted to have a predetermined pressure, the gate valve 205 is opened to unload the wafer 200 from the plurality of lift pins 207 to the outside of the gate valve 205.

Gases may be prevented from flowing backward into different buffer spaces by supplying an inert gas to the second buffer space 232b which is a second dispersion unit when the first gas is supplied or by supplying an inert gas to the first buffer space 232a which is a first dispersion unit when the second gas is supplied during the first gas supply process (S203) or the second gas supply process (S205).

Next, the relation between the first buffer space 232a which is a first dispersion unit and the second buffer space 232b which is a second dispersion unit will be described below. The dispersion holes 234a extend from the first buffer space 232a to the process space 201. The dispersion holes 234b extend from the second buffer space 232b to the process space 201. The second buffer space 232b is positioned above the first buffer space 232a. Thus, as illustrated in FIG. 1, the dispersion holes 234b extend to the process space 201 so as to pass through the inside of the first buffer space 232a from the second buffer space 232b.

Here, since the dispersion holes 234b of the second buffer space 232b pass through the inside of the first buffer space 232a, external surfaces of the dispersion holes 234b are exposed in the first buffer space 232a. The area of the exposed external surfaces of the dispersion holes 234b, i.e., a surface area of the dispersion holes 234b in the first buffer space 232a, is greater than a surface area of the dispersion holes 234b in the second buffer space 232b. That is, the surface area of the dispersion holes 234b in the first buffer chamber 232a>the surface area of the dispersion holes 234b in the second buffer chamber 232b. The area of the external surfaces of the dispersion holes 234b in the first buffer space 232a may be the same as a surface area of the dispersion holes 234b in a direction perpendicular to the wafer 200.

Molecules of a gas supplied to each of these buffer spaces are adsorbed onto inner walls of the buffer spaces. The molecules of the gases are removed in the purging processes (S204 and S206). The inventors of the present application, however, found that molecules of a certain type of gas remained on inner walls of a buffer space (in a state in which the molecules were adsorbed onto the inner walls) and were separated from the inner walls in another process, causing an unintentional reaction to occur. For example, when TiN film is formed by alternately supplying TiCl₄ and NH₃ as described above, molecules of NH₃ may be separated from inner walls of a buffer space during supply of TiCl₄ and then be supplied into the process space 201, causing a gas phase reaction of TiCl₄ and NH₃ in the process space 201 and thereby forming an undesired film. In addition, NH₄Cl which is a byproduct may be generated and prevent a desired film from being formed.

In addition, gas-facing surfaces 234g which are right sides of the external surfaces of the dispersion holes 234b in the first buffer space 232a are surfaces facing a supplied gas (i.e., surfaces facing a direction in which a gas supplied via the gas supply pipe 150a flows) and thus molecules of a gas adsorbed onto the gas-facing surfaces 234g may be easily removed when a purge gas contacts the gas-facing surfaces 234g during the purging processes (S204 and S206). In addition, the inventors found that forward direction surfaces 234h which are left sides of the external surfaces of the dispersion holes 234b in the first buffer space 232a are surfaces positioned in a forward direction in which a supplied gas flows (i.e., surfaces positioned in the same direction in which a gas supplied via the gas supply pipe 150a flows) and a purge gas is difficult to supply onto the forward direction surfaces 234h during the purging processes (S204 and S206). Thus, molecules of a gas adsorbed onto the forward direction surfaces 234h may not be removed and may thus remain. The gas-facing surfaces 234g and the forward direction surfaces 234h may vary according to the position of a gas pipe connected to a buffer space. For example, when a gas is supplied into the center of a buffer space, the gas-facing surfaces 234g are formed in a direction of the center of the buffer space and the forward direction surfaces 234h are formed in a direction of an outer circumference of the buffer space. The dispersion holes 234a and 234b are circular holes having the same diameter.

The inventors found that undesired reactions could be decreased when a gas supply position was changed according to characteristics (e.g., adsorbability, a vapor pressure, etc.) of a source gas and a reactive gas. For example, when TiCl₄ and NH₃ are supplied, undesired reactions (formation of an undesired film or generation of NH₄Cl) may be decreased by supplying NH₃, which is easier to attach to inner walls of a buffer space than TiCl₄, into a buffer space with a small surface area and supplying TiCl₄ into a buffer space with a large surface area.

Thus, according to the present embodiment, TiCl₄ which is a first gas is supplied into the first buffer space 232a with a large surface area and NH₃ which is a second gas is supplied into the second buffer space 232b with a small surface area. Here, an adsorption rate of TiCl₄ (which is the first gas) per unit area is less than that of NH₃ (which is the second gas) per unit area.

and a reactive gas is supplied to the second buffer space 232b with a small surface area in the previous embodiment, gas supply positions may be changed according to characteristics (e.g., adsorbability, a vapor pressure, etc.) of a gas.

Next, the relation between the second dispersion holes 234b of the first supply region 234e and the third dispersion holes 234c of the second supply region 234f will be described with reference to FIG. 2. The second dispersion holes 234b and the third dispersion holes 234c allow a gas present in the second buffer space 232b to pass through the inside of the process chamber 201. The second dispersion holes 234b are installed at positions facing the wafer 200. The shape and arrangement of the second dispersion holes 234b may be appropriately changed. The third dispersion holes 234c face the substrate placement unit 212 and are installed outer than an end of the wafer 200. The diameters of the third dispersion holes 234c are greater than those of the second dispersion holes 234b. Preferably, the diameters of the third dispersion holes 234c are 1.5 to 3 times those of the second dispersion holes 234b. In this case, the flow velocity of a gas in the second buffer space 232b may be maintained constant from the center of the second buffer space 232b of the outer circumference thereof. Thus, for example, the amount and concentration of a gas supplied to the wafer 200 may be controlled to be uniform within the plane of the wafer 200 using the first supply region 234e with the second dispersion holes 234b facing the wafer 200. In addition, a gas curtain may be formed between the third dispersion holes 234c and the substrate placement unit 212 by supplying a gas to the substrate placement unit 212 via the third dispersion holes 234c having the diameters greater than those of the second dispersion holes 234b. The gas curtain may reduce the speed of the flow of a gas from the center of the wafer 200 to the outer circumference thereof to increase a time that the gas remains on the wafer 200. Thus, a probability that the wafer 200 and molecules of the gas will collide with one another increases and process uniformity is improved. Therefore, a gas may be uniformly supplied within the plane of the wafer 200 via the second dispersion holes 234b. For example, when a gas curtain is formed by installing a structure for supplying an inert gas to the outer circumference to the wafer 200, the first or second gas may be diluted due to the inert gas, and the concentration of the gas may be different between the center and the outer circumference of the wafer 200. However, if a gas curtain is formed between the third dispersion holes 234c and the substrate placement unit 212 by supplying a gas to the substrate placement unit 212 via the third dispersion holes 234c having the diameters greater than those of the second dispersion holes 234b, dilution of the first or second gas may be suppressed. In addition, when a physical structure is formed instead of a gas curtain formed using an inert gas, the speed of the flow of a gas may greatly change and prevent a desired flow of the gas from being achieved. According to the present invention, the uniformity of processing the wafer 200 may be improved without causing the above problems to occur.

### Effects of the Present Embodiment

According to the present embodiment, the following one or more effects can be achieved.

(a) In a gas dispersion unit, a first supply region with first and second dispersion holes facing a substrate, and a second supply region with third dispersion holes facing a surface outer than a surface of a substrate placement unit on which the substrate is placed and having diameters greater than those of the second dispersion holes facing a surface outer than a surface of a substrate placement unit on which the substrate is placed are installed. Thus, since gas conductances of the holes of the second supply region are greater than those of the holes of the first supply region, the amount of gas components to flow in the gas dispersion unit in a direction of the diameter of the substrate may increase. Accordingly, since the amount of a gas that is supplied may be uniformized using the whole first supply region, a gas may be uniformly supplied within the plane of the substrate via the second dispersion holes.

(b) When the third dispersion holes are each formed to have a diameter greater than those of the second dispersion holes, a gas may easily flow from a center of a second buffer space to an outer circumference of the second buffer space, thereby improving the efficiency of purging the inside of the second buffer space from the center to the outer circumference. By improving the efficiency of purging the inside of the second buffer space, the amount of a gas adsorbed into the second buffer space may decrease, thus suppressing an undesired reaction or byproducts from being generated.

(c) By supplying a gas to the substrate placement unit via the third dispersion holes having the diameters greater than those of the second dispersion holes, a gas curtain may be formed between the third dispersion holes and the substrate placement unit. The gas curtain may reduce the speed of the flow of a gas from the center of a wafer to the outer circumference thereof to increase a time for the gas to remain on the wafer. In addition, a probability that the wafer and molecules of the gas will collide with one another increases and process uniformity is improved.

(d) In an apparatus designed to form a film by supplying two or more types of gases, an undesired reaction may be suppressed from being generated by supplying a gas that is easily adsorbed to a buffer space with a small surface area and a gas that is not easily adsorbed to a buffer space with a large surface area.

(e) A gas may be suppressed from being adsorbed into buffer spaces by setting a surface area of the second buffer space to which a gas that is easily adsorbed is supplied to be less than that of a first buffer space to which a gas that is not easily adsorbed is supplied.

(f) By decreasing the amount of residual NH₃, NH₄Cl or an undesired reaction may be suppressed from being generated.

### Second Embodiment

Although the first embodiment has been described above Specifically, the present invention is not limited thereto and may be embodied in many different forms without departing from the spirit and scope of the invention.

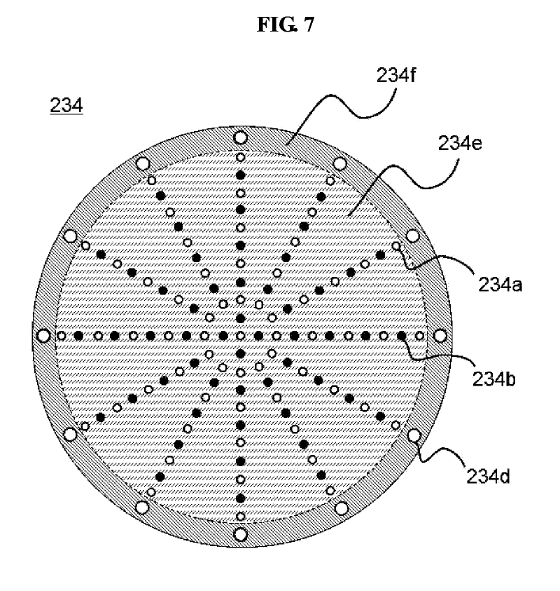

FIG. 7 illustrates a surface of a shower head 234 viewed from a side of the wafer 200 according to a second embodiment of the present invention. According to the present embodiment, fourth dispersion holes 234d are formed outer than second dispersion holes 234b. The fourth dispersion holes 234d are arranged to face the outer circumferential surface 215 of the substrate placement unit 212. A gas supplied into the process space 201 via the fourth dispersion holes 234d is supplied mainly to the outer circumferential surface 215 and is exhausted via the exhaust unit.

By installing the fourth dispersion holes 234d, the flow of a gas in the first buffer space 232a may be uniformized. Thus, the amount and concentration of a gas supplied to a surface of the wafer 200 may be controlled to be uniform from the center of the wafer 200 to the outer circumference thereof.

### Third Embodiment

Although the second embodiment has been described above Specifically, the present invention is not limited thereto and may be embodied in many different forms without departing from the spirit and scope of the invention.

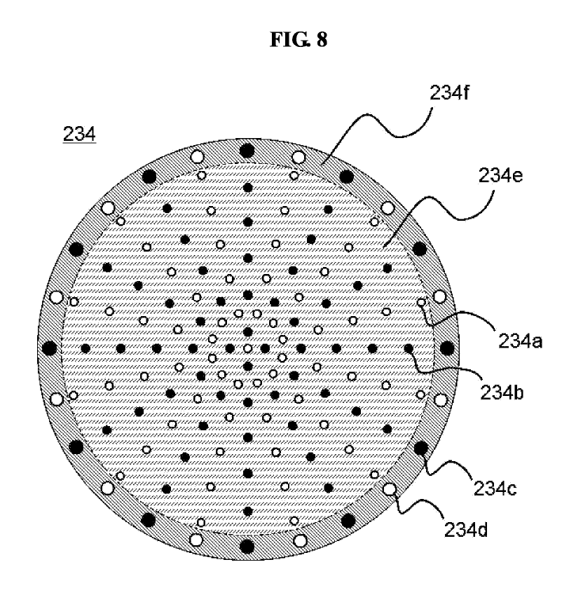

FIG. 8 illustrates a surface of a shower head 234 viewed from a side of the wafer 200 according to a third embodiment of the present invention. According to the present embodiment, third dispersion holes 234c and fourth dispersion holes 234d are disposed in positions facing the outer circumferential surface 215 of the substrate placement unit 212.

By installing the third dispersion holes 234c and the fourth dispersion holes 234d, the flow of a gas in each of the first buffer space 232a and the second buffer space 232b may be uniformized.

Although a method of forming a film by alternately supplying a source gas and a reactive gas has been described above, another method may be used provided that a degree of a gas phase reaction of the source gas and the reactive gas or the amount of byproducts generated are in allowable ranges. For example, the source gas and the reactive gas may be supplied such that supply timings thereof overlap.

In addition, although a film-forming process has been described above, exemplary embodiments of the present invention are applicable to other processes. For example, exemplary embodiments of the present invention are applicable to diffusion, oxidation, nitridation, oxynitridation, reduction, oxidation and reduction, etching, thermal treatment, etc. For example, exemplary embodiments of the present invention are applicable to a case in which a surface of a substrate or a film formed on the substrate is plasma-oxidized or plasma-nitridated using only a reactive gas. Exemplary embodiments of the present invention are also applicable to plasma annealing performed using only a reactive gas.

In addition, although a process of manufacturing a semiconductor device has been described above, exemplary embodiments of the present invention are also applicable to other manufacturing processes. For example, exemplary embodiments of the present invention are applicable to a process of manufacturing a liquid crystal device, a plasma treatment performed on a ceramic substrate, etc.

In addition, although a case in which a TiN film is formed using a titanium-containing gas (TiCl₄ gas), as a source gas and a nitrogen-containing gas (NH₃ gas) as a reactive gas has been described above, exemplary embodiments of the present invention are applicable to forming a film using different gases. For example, exemplary embodiments of the present invention are applicable to forming an oxygen-containing film, a nitrogen-containing film, a carbon-containing film, a boron-containing film, a metal-containing film, a film containing a plurality of elements among the above elements. Examples of these films may include a SiO film, a SiN film, an AlO film, a ZrO film, an HfO film, an HfAlO film, a ZrAlO film, a SiC film, a SiCN film, a SiBN film, a TiC film, a TiAlC film, etc. One or more of the above effects of the present invention can be achieved by appropriately changing a gas supply position or components included in the shower head 234 according to characteristics (adsorbability, separability, vapor pressure, etc.) of a source gas and a reactive gas used to form each of these films.

With a substrate processing apparatus, a gas dispersion unit, a method of manufacturing a semiconductor device and a non-transitory computer-readable recording medium according to an embodiment of the present invention, characteristics of a semiconductor device can be improved.

### Preferred Aspects of the Invention

Hereinafter, preferred aspects according to the present invention are supplementarily noted.

### Supplementary Note 1

According to an aspect of the present invention, there is provided a substrate processing apparatus including: a process chamber configured to process a substrate; a substrate placement unit configured to have the substrate placed thereon; and a gas dispersion unit including: a first supply region facing the substrate and including a first gas dispersion hole configured to supply a first gas and a second gas dispersion hole configured to supply a second gas; and a second supply region facing a portion of a surface of the substrate placement unit outer than a portion of the surface of the substrate placement unit occupied by the substrate and including a third gas dispersion hole having a diameter greater than that of the second gas dispersion hole and configured to supply the second gas.

### Supplementary Note 2

In the substrate processing apparatus of Supplementary note 1, preferably, the gas dispersion unit may further include a fourth gas dispersion hole in the second supply region having a diameter greater than that of the first gas dispersion hole and configured to supply the first gas.

### Supplementary Note 3

In the substrate processing apparatus of any one of Supplementary notes 1 and 2, preferably, the gas dispersion unit may further include a first buffer space connected to the first gas dispersion hole, and a second buffer space connected to the second gas dispersion hole and the third gas dispersion hole.

### Supplementary Note 4

In the substrate processing apparatus of Supplementary note 3, preferably, the third gas dispersion hole may be disposed outer than the second gas dispersion hole in the gas dispersion unit.

### Supplementary Note 5

In the substrate processing apparatus of Supplementary note 2, preferably, the gas dispersion unit may further include a first buffer space connected to the first gas dispersion hole and the fourth gas dispersion hole, and a second buffer space connected to the third gas dispersion hole.

### Supplementary Note 6

The substrate processing apparatus of any one of Supplementary notes 3 through 5, preferably, may further include a second gas inlet configured to supply the second gas to a center portion of the second buffer space.

### Supplementary Note 7

The substrate processing apparatus of any one of Supplementary notes 3 through 6, preferably, may further include a first gas supply unit configured to supply the first gas into the first buffer space; a second gas supply unit configured to supply the second gas into the second buffer space; and a control unit configured to control the first gas supply unit and the second gas supply unit to alternately supply the first gas and the second gas.

### Supplementary Note 8

In the substrate processing apparatus of any one of Supplementary notes 1 through 7, preferably, an adsorbability of the second gas may be higher than that of the first gas.

### Supplementary Note 9

In the substrate processing apparatus of any one of Supplementary notes 1 through 8, preferably, the first gas may include a source gas and the second gas may include a reactive gas.

### Supplementary Note 10

In the substrate processing apparatus of any one of Supplementary notes 1 through 9, preferably, the portion of the surface of the substrate placement unit occupied by the substrate may be lower than, by a thickness of the substrate, the portion of a surface of the substrate placement unit outer than the portion of the surface of the substrate placement unit occupied by the substrate.

### Supplementary Note 11

According to another aspect of the present invention, there is provided a gas dispersion unit configured to supply a gas into a process chamber and disposed on a substrate placement unit configured to have the substrate placed thereon, the gas dispersion unit including: a first supply region facing the substrate and including a first gas dispersion hole configured to supply a first gas and a second gas dispersion hole configured to supply a second gas; and a second supply region facing a portion of a surface of the substrate placement unit outer than a portion of the surface of the substrate placement unit occupied by the substrate and including a third gas dispersion hole having a diameter greater than that of the second gas dispersion hole and configured to supply the second gas.

### Supplementary Note 12

The gas dispersion unit of Supplementary note 11, preferably, may further include a fourth gas dispersion hole in the second supply region having a diameter greater than that of the first gas dispersion hole and configured to supply the first gas.

### Supplementary Note 13

The gas dispersion unit of any one of Supplementary notes 11 and 12, preferably, may further include a first buffer space connected to the first gas dispersion hole, and a second buffer space connected to the second gas dispersion hole and the third gas dispersion hole.

### Supplementary Note 14

In the gas dispersion unit of Supplementary note 13, preferably, the third gas dispersion hole may be disposed outer than the second gas dispersion hole in the gas dispersion unit.

### Supplementary Note 15

The gas dispersion unit of any one of Supplementary notes 13 and 14, preferably, may further include a second gas inlet configured to supply the second gas to a center portion of the second buffer space.

### Supplementary Note 16

In the gas dispersion unit of any one of Supplementary notes 11 through 15, preferably, an adsorbability of the second gas may be higher than that of the first gas

### Supplementary Note 17

In the gas dispersion unit of any one of Supplementary notes 11 through 15, preferably, the first gas may include a source gas and the second gas may include a reactive gas.

### Supplementary Note 18

According to still another aspect of the present invention, there is provided a method of manufacturing a semiconductor device, the method including: (a) placing a substrate on a substrate placement unit; (b) supplying a first gas via a gas dispersion unit, the gas dispersion unit including a first supply region facing the substrate and a second supply region facing a portion of a surface of the substrate placement unit outer than a portion of the surface of the substrate placement unit occupied by the substrate, wherein the first supply region includes a first gas dispersion hole configured to supply a first gas and a second gas dispersion hole configured to supply a second gas, and the second supply region includes a third gas dispersion hole having a diameter greater than that of the second gas dispersion hole and configured to supply the second gas; and (c) supplying the second gas.

### Supplementary Note 19

According to still another aspect of the present invention, there is provided a program configured executable by a computer, the program including: (a) placing a substrate on a substrate placement unit; (b) supplying a first gas via a gas dispersion unit, the gas dispersion unit including a first supply region facing the substrate and a second supply region facing a portion of a surface of the substrate placement unit outer than a portion of the surface of the substrate placement unit occupied by the substrate, wherein the first supply region includes a first gas dispersion hole configured to supply a first gas and a second gas dispersion hole configured to supply a second gas, and the second supply region includes a third gas dispersion hole having a diameter greater than that of the second gas dispersion hole and configured to supply the second gas; and (c) supplying the second gas.

### Supplementary Note 20

According to still another aspect of the present invention, there is provided a non-transitory computer-readable recording medium storing a program executable by a computer, the program including: (a) placing a substrate on a substrate placement unit; (b) supplying a first gas via a gas dispersion unit, the gas dispersion unit including a first supply region facing the substrate and a second supply region facing a portion of a surface of the substrate placement unit outer than a portion of the surface of the substrate placement unit occupied by the substrate, wherein the first supply region includes a first gas dispersion hole configured to supply a first gas and a second gas dispersion hole configured to supply a second gas, and the second supply region includes a third gas dispersion hole having a diameter greater than that of the second gas dispersion hole and configured to supply the second gas; and (c) supplying the second gas.

1. A substrate processing apparatus comprising:
a process chamber configured to process a substrate;
a substrate placement unit comprising: a substrate placement surface occupied by the substrate placed thereon; and an outer circumferential surface outside the substrate placement surface; and
a shower head comprising:
a first supply region facing the substrate and including a first gas dispersion hole configured to supply a first gas and a second gas dispersion hole configured to supply a second gas;
a second supply region including a third gas dispersion hole configured to supply the second gas, wherein the third gas dispersion hole faces the outer circumferential surface and has a diameter greater than that of the second gas dispersion hole;
a first buffer space connected to the first gas dispersion hole;
a second buffer space connected to the second gas dispersion hole and the third gas dispersion hole; and
a gas guide having a hole connected to a gas inlet configured to supply the second gas, the gas guide having a conical shape where a diameter thereof increases toward the substrate placed on the substrate placement unit wherein an outer circumference at a lower end of the gas guide is outer than the third gas dispersion hole.

2. The substrate processing apparatus of claim 1, wherein the second supply region further includes a fourth gas dispersion hole configured to supply the first gas, wherein the fourth gas dispersion hole has a diameter greater than that of the first gas dispersion hole.

3. (canceled)

4. The substrate processing apparatus of claim 2, wherein the fourth gas dispersion hole is connected to first buffer space.

5. (canceled)

6. The substrate processing apparatus of claim 4, wherein the gas inlet is configured to supply the second gas to a center portion of the second buffer space.

7. (canceled)

8. The substrate processing apparatus of claim 4, further comprising:
a first gas supply unit configured to supply the first gas into the first buffer space;
a second gas supply unit configured to supply the second gas into the second buffer space; and
a control unit configured to control the first gas supply unit and the second gas supply unit to alternately supply the first gas and the second gas.

9. The substrate processing apparatus of claim 1, wherein an adsorbability of the second gas is higher than that of the first gas.

10. The substrate processing apparatus of claim 1, wherein the first gas comprises a source gas and the second gas comprises a reactive gas.

11. A shower head configured to supply a gas into a process chamber and disposed above a substrate placement unit having a substrate placement surface occupied by a substrate placed thereon and an outer circumferential surface outer than the substrate placement surface, the shower head comprising:
a first supply region facing the substrate and including a first gas dispersion hole configured to supply a first gas and a second gas dispersion hole configured to supply a second gas;
a second supply region including a third gas dispersion hole configured to supply the second gas, wherein the third gas dispersion hole faces the outer circumferential surface and has a diameter greater than that of the second gas dispersion hole;
a first buffer space connected to the first gas dispersion hole;
a second buffer space connected to the second gas dispersion hole and the third gas dispersion hole; and
a gas guide having a hole connected to a gas inlet configured to supply the second gas, the gas guide having a conical shape where a diameter thereof increases toward the substrate placed on the substrate placement unit wherein an outer circumference at a lower end of the gas guide is outer than the third gas dispersion hole.

12. The shower head of claim 11, wherein the second supply region further includes a fourth gas dispersion hole configured to supply the first gas, wherein the fourth gas dispersion hole has diameter greater than that of the first gas dispersion hole.

13. (canceled)

14. The shower head of claim 12, wherein the fourth gas dispersion hole is connected to the first buffer space.

15. (canceled)

16. The shower head of claim 14, wherein the gas inlet is configured to supply the second gas to a center portion of the second buffer space.

17. The shower head of claim 11, wherein an adsorbability of the second gas is higher than that of the first gas.
